(19) United States
(12) Patent Application Publication
(10) Pub. No.: US 2025/0112178 A1
(43) Pub. Date: Apr. 3, 2025

(54) GAMING DISPLAY SYSTEMS USING INTEGRATED ELECTROSTATIC DISCHARGE PROTECTION

(71) Applicant: LNW Gaming, Inc., Las Vegas, NV (US)

(72) Inventors: Nicholas BANAS, Henderson, NV (US); Pablito TOLENTINO, JR., North Las Vegas, NV (US)

(21) Appl. No.: 18/886,076

(22) Filed: Sep. 16, 2024

Related U.S. Application Data
(60) Provisional application No. 63/587,510, filed on Oct. 3, 2023.

(51) Int. Cl. H01L 23/60; G06F 3/14; H01L 25/04; H05K 9/00

(52) U.S. Cl. CPC H01L 23/60; G06F 3/1423; H01L 25/042; H05K 9/0058

(57) ABSTRACT

Gaming systems and methods are described herein for gaming machines including a primary display configured to present primary game video data and at least one secondary display assembly configured to present secondary game video data. The secondary display assembly includes a plurality of light emitting diodes (LEDs) configured to present video data towards an external area surrounding the gaming machine, a display substrate coupled to the LEDs and including display circuitry electrically coupling the LEDs together for presenting the secondary game video data, an insulation layer physically coupled to the display substrate and surrounding the LEDs, and an electrostatic discharge (ESD) layer physically coupled to the insulation layer and physically spaced apart from the LEDs, the ESD layer being electrically conductive to guide electrostatic discharge away from the LEDs, wherein the ESD layer is electrically isolated from the display circuitry by the insulation layer.

### CROSS-REFERENCE TO RELATED APPLICATIONS

This application claims the benefit of priority to U.S. Provisional Application No. 63/587,510, filed Oct. 3, 2023, the contents of which are hereby incorporated by reference in their entirety herein.

### COPYRIGHT

A portion of the disclosure of this patent document contains material which is subject to copyright protection. The copyright owner has no objection to the facsimile reproduction by anyone of the patent disclosure, as it appears in the Patent and Trademark Office patent files or records, but otherwise reserves all copyright rights whatsoever. Copyright 2023, LNW Gaming, Inc.

### FIELD OF THE INVENTION

The present invention relates to a technological improvement to gaming systems including gaming machines, particularly providing electrostatic discharge (ESD) protection for gaming machine display systems.

### BACKGROUND OF THE INVENTION

Gaming machines include a variety of electronic devices that operate together and/or in parallel to facilitate the various functions of the gaming machines. For example, electronic devices may be used to conduct game-logic, detect sensory events, output various audiovisual and/or tactile presentations, and the like. Two example electronic assemblies found on gaming machines are display assemblies for presenting video data and lighting assemblies that present lighting sequences (i.e., visual presentations that do not recreate or present image or video data). At least some known gaming machines include a primary display with one or more secondary lighting assemblies to present emotive lighting to supplement the game content presented by the primary display. The display assemblies and lighting assemblies rely upon a plurality of electronic components to facilitate the corresponding visual presentations, such as light-emitting diodes (LEDs) that convert electrical signals into visual light.

Electronic devices such as LEDs may require or recommend (e.g., through regulatory requirements) certain operating conditions, such as input voltages and currents, operating temperatures, pins or coupling points designated for certain functions, and the like to facilitate the intended function of the devices for a rated lifetime. One technical challenge of electronic systems is preventing or otherwise reducing external factors that impact the operating conditions of the electronic devices. Electromagnetic interference (EMI), radiation, thermal runaway, and the like are all example external factors that may adversely affect electronic systems. Another example is electrostatic discharge (ESD), resulting from a sudden and momentary flow of electric current between two electrically charged objects (e.g., an LED and a person's hand). The electric current and/or voltage caused by ESD may be outside the recommended conditions of the electronic device, thereby causing damaging that may negatively affect the electronic device (including device failure).

For gaming machines, ESD is typically a product of external devices or people approaching or contacting the gaming machine as internal sources of ESD can be managed through sufficient spacing, arrangement, and material choice of internal components during the design of the gaming machine. To protect against or otherwise prevent ESD at gaming machines from external sources, at least some known machines space the electronic devices from any external access. For example, secondary lighting assemblies include physical barriers and air gaps separating the LEDs from any external devices and/or people while enabling lighting to pass through.

However, advances and improvements in gaming machines include consideration of replacing secondary lighting assemblies with secondary display assemblies for presenting secondary video data. The secondary display assemblies may incorporate newer display technologies, such as organic LED (OLED), mini-LED, and micro-LED that enable flexible panel arrangements and substantially “bezel-less” combinations of panels. In contrast to secondary lighting assemblies, the physical barriers and air gaps negatively affect the use of displays by reducing the image quality perceived external to the gaming machine, thereby resulting in an image that may be perceived as dimmer, limited or incorrect colors, and/or introducing other undesirable visual artifacts. Moreover, the physical barriers may limit or otherwise add complexity to flexible displays configured to be installed in curved configurations. Additionally, air gaps are susceptible to dust, smoke, and other particulate ingress that further affect the image quality of the secondary displays, thereby necessitating increased maintenance and care.

Accordingly, what is needed is a new and improved means of providing ESD protection for gaming machines incorporating new secondary display assemblies.

### SUMMARY OF THE INVENTION

According to an embodiment of the present invention, there is provided gaming systems and methods comprising gaming machines including a primary display configured to present primary game video data and at least one secondary display assembly configured to present secondary game video data. The secondary display assembly includes a plurality of light emitting diodes (LEDs) configured to present video data towards an external area surrounding the gaming machine, a display substrate coupled to the LEDs and including display circuitry electrically coupling the LEDs together for presenting the secondary game video data, an insulation layer physically coupled to the display substrate and surrounding the LEDs, and an electrostatic discharge (ESD) layer physically coupled to the insulation layer and physically spaced apart from the LEDs, the ESD layer being electrically conductive to guide electrostatic discharge away from the LEDs, wherein the ESD layer is electrically isolated from the display circuitry by the insulation layer.

Additional aspects of the invention will be apparent to those of ordinary skill in the art in view of the detailed description of various embodiments, which is made with reference to the drawings, a brief description of which is provided below.

### BRIEF DESCRIPTION OF THE DRAWINGS

FIG. 1 is a block diagram of an example gaming machine according to an embodiment of the present invention.

FIG. 2 is a data flow diagram between a display controller and several display assemblies of a gaming machine according to an embodiment of the present invention.

FIG. 3 is a block diagram of a gaming system according to an embodiment of the present invention.

FIG. 4 is a perspective view of a free-standing gaming machine according to an embodiment of the present invention.

FIG. 5 is a top-down view of the gaming machine shown in FIG. 4.

FIG. 6 is a view of an example secondary display assembly according to an embodiment of the present invention.

FIG. 7 is a cross-sectional block diagram of an example secondary display panel according to an embodiment of the present invention.

FIG. 8A is a cross-sectional view of an example display panel according to an embodiment of the present invention.

FIG. 8B is a cross-sectional view of an example display panel with an integrated grounding post according to an embodiment of the present invention.

FIG. 8C is a cross-sectional view of an example display panel with an electrically grounded mounting bracket according to an embodiment of the present invention.

FIG. 9 is a block diagram of an example method for assembling and installing secondary display assembly of a gaming machine according to an embodiment of the present invention.

FIG. 10 is a block diagram of an example method of operating a gaming machine according to an embodiment of the present invention.

While the invention is susceptible to various modifications and alternative forms, specific embodiments have been shown by way of example in the drawings and will be described in detail herein. It should be understood, however, that the invention is not intended to be limited to the particular forms disclosed. Rather, the invention is to cover all modifications, equivalents, and alternatives falling within the spirit and scope of the invention as defined by the appended claims.

### DETAILED DESCRIPTION

While this invention is susceptible of embodiment in many different forms, there is shown in the drawings and will herein be described in detail preferred embodiments of the invention with the understanding that the present disclosure is to be considered as an exemplification of the principles of the invention and is not intended to limit the broad aspect of the invention to the embodiments illustrated. For purposes of the present detailed description, the singular includes the plural and vice versa (unless specifically disclaimed); the words “and” and “or” shall be both conjunctive and disjunctive; the word “all” means “any and all”; the word “any” means “any and all”; and the word “including” means “including without limitation.”

For purposes of the present detailed description, the terms “wagering game,” “casino wagering game,” “gambling,” “slot game,” “casino game,” and the like include games in which a player places at risk a sum of money or other representation of value, whether or not redeemable for cash, on an event with an uncertain outcome, including without limitation those having some element of skill. In some embodiments, the wagering game involves wagers of real money, as found with typical land-based or online casino games. In other embodiments, the wagering game additionally, or alternatively, involves wagers of non-cash values, such as virtual currency, and therefore may be considered a social or casual game, such as would be typically available on a social networking web site, other web sites, across computer networks, or applications on mobile devices (e.g., phones, tablets, etc.). When provided in a social or casual game format, the wagering game may closely resemble a traditional casino game, or it may take another form that more closely resembles other types of social/casual games.

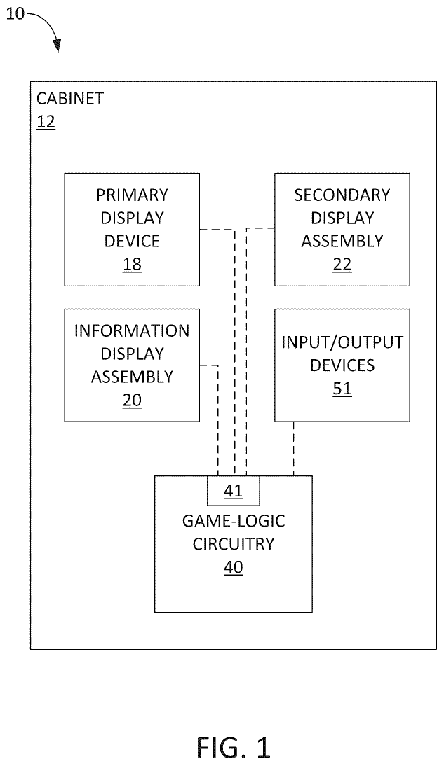

FIG. 1 depicts a block diagram of an example gaming machine 10 of a gaming system. The gaming machine 10 includes a cabinet 12 configured to secure and/or house various components of the gaming machine. The cabinet 12 may be divided into a plurality of subassemblies can be assembled separately or otherwise enable modular assembly, maintenance, or otherwise independent structure. For example, a display assembly may be coupled to the cabinet 12 via a display cabinet subassembly.

The gaming machine 10 further comprises a primary display assembly 18, an information display assembly 20, a secondary display assembly 22, a plurality of input and output devices 51, and game-logic circuitry in communication with the display assemblies 18, 20, 22 and the input and output devices. The game-logic circuitry 40 (described in detail further herein) includes a display controller system 41, which is configured to generate image and video data associated with one or more games and provide the corresponding data to each respective display assembly 18, 20, 22 to provide a unified game presentation (where a “unified” game presentation may also include independent presentation sequences presenting in parallel to each other across the display assemblies). In some embodiments, the display controller system 41 includes separate controllers for each display assembly 18, 20, 22. In other embodiments, a single display controller 41 manages multiple display assemblies at once. In certain embodiments, a portion of the display controller 41 may be integrated within each display assembly 18, 20, 22 to perform one or more functions of the display controller system 41 as described herein.

Each display assembly 18, 20, 22 includes one or more electronic display devices configured to present image and video data. Each assembly may include additional components to facilitate the functionality of the display devices, such as power electronic assemblies, physical structures (e.g., mounting brackets, cable guides, etc.), heat sinks, and the like. In some embodiments, a display assembly may be configured to be a physically combined to form a single subassembly coupled to the cabinet 12. Additionally or alternatively, some display assemblies may include a plurality of physically independent display subassemblies. In one example, the secondary display assembly 22 includes two subassemblies positioned adjacent to two opposing sides of the primary display assembly 18.

The distinction between the display assemblies 18, 20, 22 is based on the intended content of the display assembly and the configuration of the display assembly within the cabinet 12. In the example embodiment, the primary display assembly 18 is configured to present primary game content. The primary display content is configured to be the primary focus of a player seated or standing at the gaming machine 10. For example, a symbol array may be presented by the primary display assembly 18 for play of a reel-based wagering game. Other suitable content may be integrated within the presentation by the primary display assembly 18 to attract player attention to certain information or otherwise enable the player to monitor desired information, such as the current time, weather, or date.

The information display assembly 20 is configured to present information supplemental to the content presented by the primary display assembly 18. Meters, connection status (with a personal computing device of the player), player account information, and the like are presented by the information display assembly 20 to free the primary display assembly 18 to present game content.

The secondary display assembly 22 is configured to present secondary game content associated with the primary game content. The secondary game content may include game elements and/or presentation elements according to the theme of the game content, the configuration of the secondary display assembly 22 within the gaming machine 10, and the like.

The input and/or output devices 51 are in communication with the game-logic circuitry 40 to facilitate the detection of particular inputs (e.g., player input, credit inputs, network connections with personal computing devices) and present various outputs (e.g., credit outputs, audio, etc.). In one example, the input and/or output devices 51 may include a touchscreen for presenting digital buttons and other interactable inputs and receiving corresponding player input. Other suitable examples of the devices 51 are described herein.

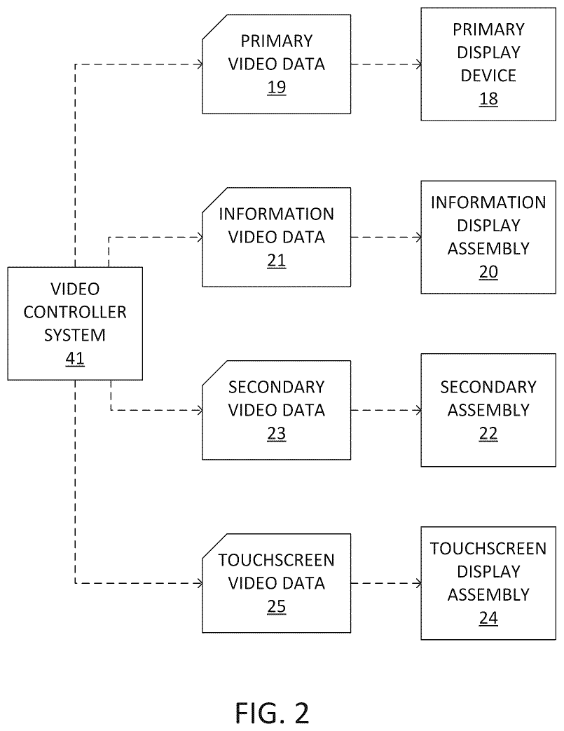

FIG. 2 depicts data communication between the display controller system 41 to the display assemblies of the gaming machine 10. In particular, the display controller system 41 is configured to generate and transmit primary video data 19 to the primary display assembly 18, information video data 21 to the information display assembly 20, secondary video data 23 to the secondary display assembly 22, and touchscreen video data 25 to a touchscreen display assembly 24 (i.e., of the input/output devices 51). Each set of video data includes video frames (i.e., images) and/or other suitable data associated with a video stream that is presented by the corresponding display assemblies. Other suitable data may include, for example and without limitation, metadata associated with timestamps for video timing (e.g., to produce unified presentations across multiple display assemblies), control data for adjusting the output of the display assemblies, audio data, and the like.

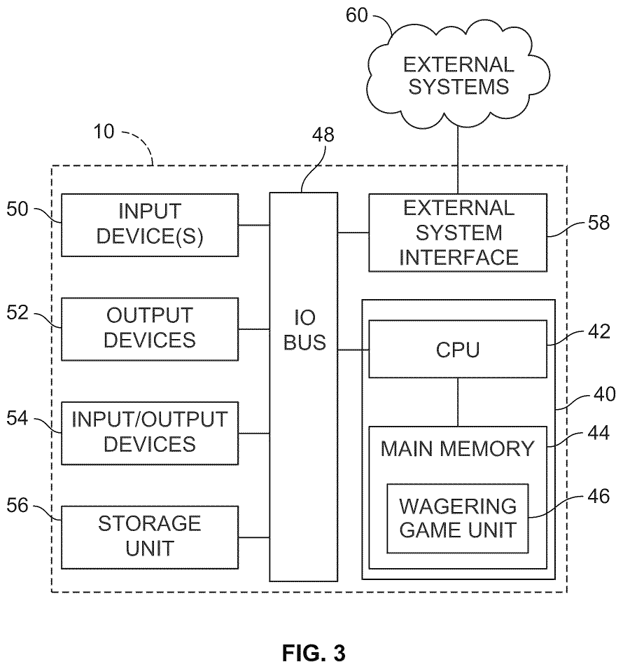

Turning now to FIG. 3, there is shown a block diagram of the gaming-machine architecture. The gaming machine 10 includes the game-logic circuitry 40 securely housed within a locked box inside the gaming cabinet 12 (see FIG. 1). The game-logic circuitry 40 includes a central processing unit (CPU) 42 connected to a main memory 44 that comprises one or more memory devices. The CPU 42 includes any suitable processor(s), such as those made by Intel and AMD. By way of example, the CPU 42 includes a plurality of microprocessors including a master processor, a slave processor, and a secondary or parallel processor. Game-logic circuitry 40, as used herein, comprises any combination of hardware, software, or firmware disposed in or outside of the gaming machine 10 that is configured to communicate with or control the transfer of data between the gaming machine 10 and a bus, another computer, processor, device, service, or network. The game-logic circuitry 40, and more specifically the CPU 42, comprises one or more controllers or processors and such one or more controllers or processors need not be disposed proximal to one another and may be located in different devices or in different locations. The game-logic circuitry 40, and more specifically the main memory 44, comprises one or more memory devices which need not be disposed proximal to one another and may be located in different devices or in different locations. The game-logic circuitry 40 is operable to execute all of the various gaming methods and other processes disclosed herein. The main memory 44 includes a wagering-game unit 46. In one embodiment, the wagering-game unit 46 causes wagering games to be presented, such as video poker, video blackjack, video slots, video lottery, etc., in whole or part.

The game-logic circuitry 40 is also connected to an input/output (I/O) bus 48, which can include any suitable bus technologies, such as an AGTL+ frontside bus and a PCI backside bus. The I/O bus 48 is connected to various input devices 50, output devices 52, and input/output devices 54 such as those discussed above in connection with FIG. 1. The I/O bus 48 is also connected to a storage unit 56 and an external-system interface 58, which is connected to external system(s) 60 (e.g., wagering-game networks).

The external system 60 includes, in various aspects, a gaming network, other gaming machines or terminals, a gaming server, a remote controller, communications hardware, or a variety of other interfaced systems or components, in any combination. In yet other aspects, the external system 60 comprises a player's portable electronic device (e.g., cellular phone, electronic wallet, etc.) and the external-system interface 58 is configured to facilitate wireless communication and data transfer between the portable electronic device and the gaming machine 10, such as by a near-field communication path operating via magnetic-field induction or a frequency-hopping spread spectrum RF signals (e.g., Bluetooth, etc.).

The gaming machine 10 optionally communicates with the external system 60 such that the gaming machine 10 operates as a thin, thick, or intermediate client. The game-logic circuitry 40-whether located within (“thick client”), external to (“thin client”), or distributed both within and external to (“intermediate client”) the gaming machine 10—is utilized to provide a wagering game on the gaming machine 10. In general, the main memory 44 stores programming for a random number generator (RNG), game-outcome logic, and game assets (e.g., art, sound, etc.)—all of which obtained regulatory approval from a gaming control board or commission and are verified by a trusted authentication program in the main memory 44 prior to game execution. The authentication program generates a live authentication code (e.g., digital signature or hash) from the memory contents and compares it to a trusted code stored in the main memory 44. If the codes match, authentication is deemed a success and the game is permitted to execute. If, however, the codes do not match, authentication is deemed a failure that must be corrected prior to game execution. Without this predictable and repeatable authentication, the gaming machine 10, external system 60, or both are not allowed to perform or execute the RNG programming or game-outcome logic in a regulatory-approved manner and are therefore unacceptable for commercial use. In other words, through the use of the authentication program, the game-logic circuitry facilitates operation of the game in a way that a person making calculations or computations could not.

When a wagering-game instance is executed, the CPU 42 (comprising one or more processors or controllers) executes the RNG programming to generate one or more pseudo-random numbers. The pseudo-random numbers are divided into different ranges, and each range is associated with a respective game outcome. Accordingly, the pseudo-random numbers are utilized by the CPU 42 when executing the game-outcome logic to determine a resultant outcome for that instance of the wagering game. The resultant outcome is then presented to a player of the gaming machine 10 by accessing the associated game assets, required for the resultant outcome, from the main memory 44. The CPU 42 causes the game assets to be presented to the player as outputs from the gaming machine 10 (e.g., audio and video presentations). Instead of a pseudo-RNG, the game outcome may be derived from random numbers generated by a physical RNG that measures some physical phenomenon that is expected to be random and then compensates for possible biases in the measurement process. Whether the RNG is a pseudo-RNG or physical RNG, the RNG uses a seeding process that relies upon an unpredictable factor (e.g., human interaction of turning a key) and cycles continuously in the background between games and during game play at a speed that cannot be timed by the player. Accordingly, the RNG cannot be carried out manually by a human and is integral to operating the game.

The gaming machine 10 may be used to play central determination games, such as electronic pull-tab and bingo games. In an electronic pull-tab game, the RNG is used to randomize the distribution of outcomes in a pool and/or to select which outcome is drawn from the pool of outcomes when the player requests to play the game. In an electronic bingo game, the RNG is used to randomly draw numbers that players match against numbers printed on their electronic bingo card.

The gaming machine 10 may include additional peripheral devices or more than one of each component shown in FIG. 3. Any component of the gaming-machine architecture includes hardware, firmware, or tangible machine-readable storage media including instructions for performing the operations described herein. Machine-readable storage media includes any mechanism that stores information and provides the information in a form readable by a machine (e.g., gaming terminal, computer, etc.). For example, machine-readable storage media includes read only memory (ROM), random access memory (RAM), magnetic-disk storage media, optical storage media, flash memory, etc.

In accord with various methods of conducting a wagering game on a gaming system in accord with the present concepts, the wagering game includes a game sequence in which a player makes a wager, and a wagering-game outcome is provided or displayed in response to the wager being received or detected. The wagering-game outcome, for that particular wagering-game instance, is then revealed to the player in due course following initiation of the wagering game. The method comprises the acts of conducting the wagering game using a gaming apparatus, such as the gaming machine 10 depicted in FIG. 1, following receipt of an input from the player to initiate a wagering-game instance. The gaming machine 10 then communicates the wagering-game outcome to the player via one or more output devices (e.g., primary presentation device 18 or information presentation device 20) through the presentation of information such as, but not limited to, text, graphics, static images, moving images, etc., or any combination thereof. In accord with the method of conducting the wagering game, the game-logic circuitry 40 transforms a physical player input, such as a player's pressing of a “Spin” touch key or button, into an electronic data signal indicative of an instruction relating to the wagering game (e.g., an electronic data signal bearing data on a wager amount).

In the aforementioned method, for each data signal, the game-logic circuitry 40 is configured to process the electronic data signal, to interpret the data signal (e.g., data signals corresponding to a wager input), and to cause further actions associated with the interpretation of the signal in accord with stored instructions relating to such further actions executed by the controller. As one example, the CPU 42 causes the recording of a digital representation of the wager in one or more storage media (e.g., storage unit 56), the CPU 42, in accord with associated stored instructions, causes the changing of a state of the storage media from a first state to a second state. This change in state is, for example, effected by changing a magnetization pattern on a magnetically coated surface of a magnetic storage media or changing a magnetic state of a ferromagnetic surface of a magneto-optical disc storage media, a change in state of transistors or capacitors in a volatile or a non-volatile semiconductor memory (e.g., DRAM, etc.). The noted second state of the data storage media comprises storage in the storage media of data representing the electronic data signal from the CPU 42 (e.g., the wager in the present example). As another example, the CPU 42 further, in accord with the execution of the stored instructions relating to the wagering game, causes the primary presentation device 18, other presentation device, or other output device (e.g., speakers, lights, communication device, etc.) to change from a first state to at least a second state, wherein the second state of the primary presentation device comprises a visual representation of the physical player input (e.g., an acknowledgement to a player), information relating to the physical player input (e.g., an indication of the wager amount), a game sequence, an outcome of the game sequence, or any combination thereof, wherein the game sequence in accord with the present concepts comprises acts described herein. The aforementioned executing of the stored instructions relating to the wagering game is further conducted in accord with a random outcome (e.g., determined by the RNG) that is used by the game-logic circuitry 40 to determine the outcome of the wagering-game instance. In at least some aspects, the game-logic circuitry 40 is configured to determine an outcome of the wagering-game instance at least partially in response to the random parameter.

In one embodiment, the gaming machine 10 and, additionally or alternatively, the external system 60 (e.g., a gaming server), means gaming equipment that meets the hardware and software requirements for fairness, security, and predictability as established by at least one state's gaming control board or commission. Prior to commercial deployment, the gaming machine 10, the external system 60, or both and the casino wagering game played thereon may need to satisfy minimum technical standards and require regulatory approval from a gaming control board or commission (e.g., the Nevada Gaming Commission, Alderney Gambling Control Commission, National Indian Gaming Commission, etc.) charged with regulating casino and other types of gaming in a defined geographical area, such as a state. By way of non-limiting example, a gaming machine in Nevada means a device as set forth in NRS 463.0155, 463.0191, and all other relevant provisions of the Nevada Gaming Control Act, and the gaming machine cannot be deployed for play in Nevada unless it meets the minimum standards set forth in, for example, Technical Standards 1 and 2 and Regulations 5 and 14 issued pursuant to the Nevada Gaming Control Act. Additionally, the gaming machine and the casino wagering game must be approved by the commission pursuant to various provisions in Regulation 14. Comparable statutes, regulations, and technical standards exist in or are used in other gaming jurisdictions, including for example GLI Standard #11 of Gaming Laboratories International (which defines a gaming device in Section 1.5) and N.J.S.A 5:12-23, 5:12-45, and all other relevant provisions of the New Jersey Casino Control Act. As can be seen from the description herein, the gaming machine 10 may be implemented with hardware and software architectures, circuitry, and other special features that differentiate it from general-purpose computers (e.g., desktop PCs, laptops, and tablets).

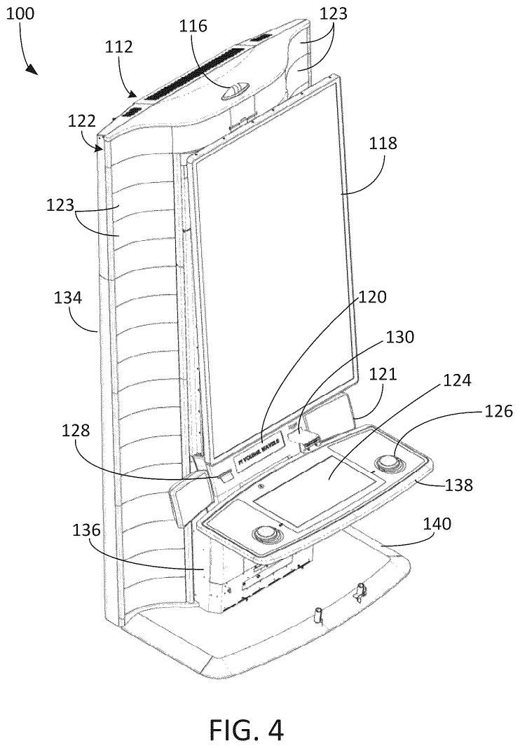

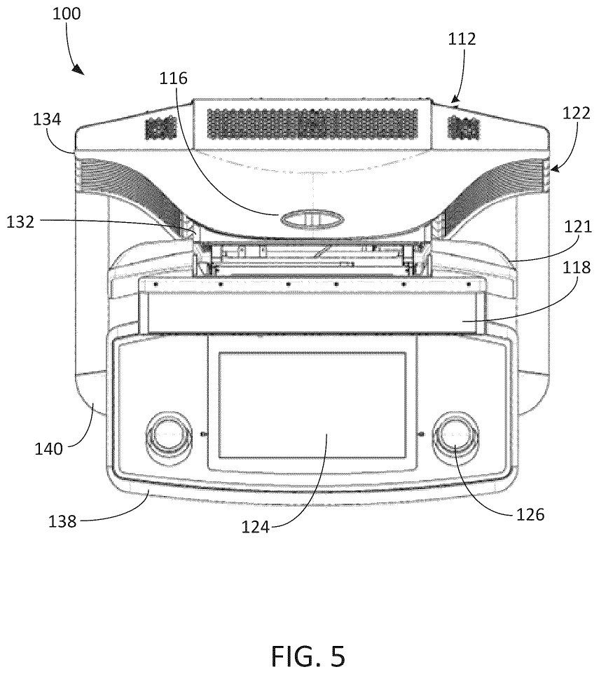

FIGS. 4 and 5 depict an example gaming machine 100 of a gaming system according to one or more embodiments of the present disclosure. In particular, FIG. 4 depicts a perspective view of the gaming machine 100, and FIG. 5 depicts a top-down view of the gaming machine 100. In other embodiments, the gaming machine 100 includes additional, fewer, or alternative components in a similar or different configuration relative to the illustrated embodiment shown in FIGS. 4 and 5, including those components and configurations described elsewhere herein.

The gaming machine 100 is similar to those operated in gaming establishments, such as casinos. With regard to the present invention, the gaming machine 100 may be any type of gaming terminal or machine and may have varying structures and methods of operation. For example, in some aspects, the gaming machine 100 is an electromechanical gaming terminal configured to play mechanical slots, whereas in other aspects, the gaming machine is an electronic gaming terminal configured to play a video casino game, such as slots, keno, poker, blackjack, roulette, craps, etc. The gaming machine 100 may take any suitable form, such as floor-standing models as shown, handheld mobile units, bartop models, workstation-type console models, etc. Further, the gaming machine 100 may be primarily dedicated for use in playing wagering games, or may include non-dedicated devices, such as mobile phones, personal digital assistants, personal computers, etc. Exemplary types of gaming machines are disclosed in U.S. Pat. Nos. 6,517,433, 8,057,303, and 8,226,459, which are incorporated herein by reference in their entireties.

The gaming machine 100 illustrated in FIGS. 4 and 5 comprises a gaming cabinet 112 that securely houses various input devices, output devices, input/output devices, internal electronic/electromechanical components, and wiring. The cabinet 112 includes exterior walls, interior walls, and shelves for mounting the internal components and managing the wiring, and one or more front doors that are locked and require a physical or electronic key to gain access to the interior compartment of the cabinet 112 behind the locked door. A notification mechanism 116, such as a candle or tower light, is mounted to the top of the cabinet 112. It flashes to alert an attendant that change is needed, a hand pay is requested, or there is a potential problem with the gaming machine 100.

The input devices, output devices, and input/output devices are disposed on, and securely coupled to, the cabinet 112. By way of example, the output devices include a primary presentation device 118, an information presentation device 120, a secondary display assembly 122, and one or more audio speakers 121. The primary presentation device 118 and/or the information presentation device 120 (which may be sometimes referred to herein as “primary display device 118” and “information display device 120”) may be a mechanical-reel display device, a video display device, or a combination thereof. In one such combination disclosed in U.S. Pat. No. 6,517,433, a transmissive video display is disposed in front of the mechanical-reel display to portray a video image superimposed upon electro-mechanical reels. In another combination disclosed in U.S. Pat. No. 7,654,899, a projector projects video images onto stationary or moving surfaces. In yet another combination disclosed in U.S. Pat. No. 7,452,276, miniature video displays are mounted to electro-mechanical reels and portray video symbols for the game. In a further combination disclosed in U.S. Pat. No. 8,591,330, flexible displays such as OLED or e-paper displays are affixed to electro-mechanical reels. The aforementioned U.S. Pat. Nos. 6,517,433, 7,654,899, 7,452,276, and 8,591,330 are incorporated herein by reference in their entireties.

The presentation devices 118, 120, the secondary display assembly 122, the audio speakers 121, lighting assemblies, and/or other devices associated with presentation are collectively referred to as a “presentation assembly” of the gaming machine 100. The presentation assembly may include one presentation device (e.g., the primary presentation device 118), some of the presentation devices of the gaming machine 100, or all of the presentation devices of the gaming machine 100 (including presentation subassemblies like the secondary display assembly 122). The presentation assembly may be configured to present a unified presentation sequence formed by visual, audio, tactile, and/or other suitable presentation means, or the devices of the presentation assembly may be configured to present respective presentation sequences or respective information.

The presentation assembly, and more particularly the primary presentation device 118 and/or the information presentation device 120, variously presents information associated with wagering games, non-wagering games, community games, progressives, advertisements, services, premium entertainment, text messaging, emails, alerts, announcements, broadcast information, subscription information, etc. appropriate to the particular mode(s) of operation of the gaming machine 100. The gaming machine 100 may include a touch screen(s) 124 mounted over a corresponding presentation device, buttons 126 on a button panel, a bill/ticket acceptor and/or dispenser 128, a card reader/writer 130, and player-accessible ports (e.g., audio output jack for headphones, video headset jack, USB port, wireless transmitter/receiver, etc.). It should be understood that numerous other peripheral devices and other elements exist and are readily utilizable in any number of combinations to create various forms of a gaming machine in accord with the present concepts.

In the example embodiment, the secondary display assembly 122 includes a plurality of flexible secondary display panels 123. The secondary display panels 123 are configured to present video content rather than emotive lighting (i.e., visual presentation focused on color or light intensity rather than recreating a particular image or video stream). In at least some embodiments, the secondary display panels 123 are flexible to facilitate a particular configuration of the panels 123 relative to other components of the gaming machine 100 as described herein. Example display technologies that facilitate such a flexible structure include, but are not limited to, OLED panels, micro-LED panels, mini-LED panels, and e-ink panels. Such display technologies, such as micro-LED, further facilitate the display panels to be combined together without or with minimal bezels therebetween, thereby resulting in a display assembly that presents images and video across the panels 123 with limited obstructions from the barriers and edges between the panels 123. In other embodiments, the curvature of the secondary display panels 123 is formed to be rigid within a manufacturing or assembly process associated with the panels 123. The particular curvature of each panel 123 may be maintained through a support structure integrated within the secondary display panels 123 and/or within the cabinet 112 as described herein.

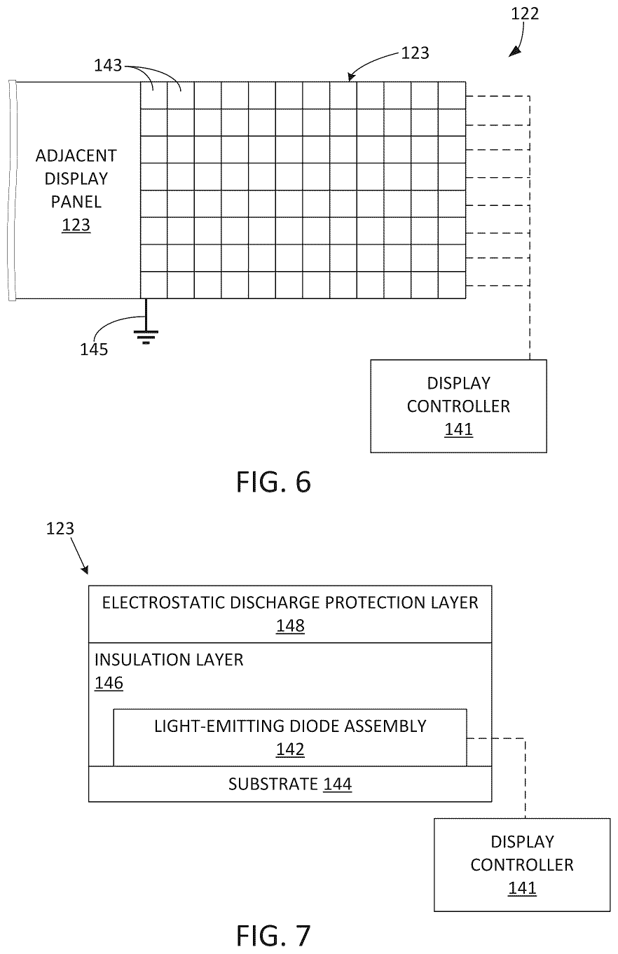

The secondary display panels 123 include one or more light-emitting diodes (LEDs) that emit light. The emitted light is either configured to be emitted at particular wavelengths, thereby resulting in light of a particular color, or the light passes through a color filter system to create light of predefined colors. By arranging the LEDs and controlling the color, intensity, and other aspects of the emitted light as perceived by the player, graphical images can be presented through the secondary display panels 123. Further details of the secondary display panels 123 are described herein with respect to FIG. 6.

The cabinet 112 of the gaming machine 100 is formed from several structural components that house or otherwise mount particular components of the gaming machine 100. For example, the cabinet 112 includes a primary display structure 132 (shown in FIG. 5), a secondary display structure 134, a center structure 136, an input panel 138, and a foot or base 140. These structures are at least defined by the corresponding components mounted to each structure. In some embodiments, the structures are distinctive, modular structures that are combined together to form the gaming machine 100. In other embodiments, at least a portion of the structures may be integrated together. For example, the primary display structure 132, the center structure 136, and the base 140 may be a single integrated housing. It is to be understood that the mounting structure of each structural component of the cabinet 112 is configurable to facilitate the particular design and mounting features of the components held by each respective structure component. For example, the number and placement of fastener mounting points, hooks, brackets, wire guides, and the like of a given structural component of the cabinet 112 may vary depending upon the particular structure of, for example, a display device to be mounted.

The primary display structure 132 is configured to mount and support the primary display device 118. As can be seen in FIG. 5, the primary display structure 132 mounts the primary display device 118 in a manner that is in front of the secondary display assembly 122 to create a sense of depth between the primary display device 118 and the secondary display assembly 122. The curvature of the secondary display assembly 122 and the partial obscuring of the secondary display assembly 122 also creates a unique configuration where the content presented by the secondary display assembly 122 appears to flow from behind the primary display device 118.

In the example embodiment, the primary display structure 132 extends outward from the secondary display structure 134 that is configured to mount the secondary display assembly 122. The secondary display structure 134 includes a mounting structure configured to facilitate the mounting of the secondary display assembly 122, which may include a configuration of mounting structure for mounting flexible display panels at a particular curvature as described herein. In at least some embodiments, the display panels 123 include mounting components and/or features for physically coupling to the secondary display structure 134 and/or other display panels 123, such as the adjacent display panels 123 to a given panel 123. In the illustrated embodiment, the secondary display structure 134 extends along two opposing sides of the primary display device 118 from the base 140 to the top of the cabinet 112 as well as above the primary display device 118. In some embodiments, the secondary display assembly 122 and the secondary display structure 134 may be considered as a single display assembly and display structure, respectively. In other embodiments, the gaming machine 100 includes at least two sets of the secondary display assembly 122 and the secondary display structure 134, where embodiments with two sets include one set on either side of the primary display device 118.

The center structure 136 is configured to house one or more internal components of the gaming machine 100 (e.g., the game-logic circuitry) to facilitate the functionality of the gaming machine 100 as described herein. The center structure 136 in the illustrated embodiment further includes the information display device 120 and at least some of the input and output devices (e.g., the speakers 121, the ticket acceptor/dispenser, and the card reader 130). In other embodiments, the primary display structure 132 is configured to mount the information display device 120. At least some of the other structural components of the cabinet 112 extend from the center structure 136. For example, the input panel 138 is configured to house one or more input devices (e.g., the touch screen 124 and the buttons 126) for player input, and the input panel 138 extends from the center structure 136 such that a player can comfortably sit or stand at the gaming machine 100 depending upon the configuration of the machine 100. The base 140 is configured to extend at least under the center structure 136 (and, in some embodiments, the secondary display structure 134) to support the cabinet 112 on a ground surface. The base 140 may be a singular support element or a plurality of elements, such as a set of feet.

The player input devices, such as the touch screen 124, buttons 126, a mouse, a joystick, a gesture-sensing device, a voice-recognition device, and a virtual-input device, accept player inputs and transform the player inputs to electronic data signals indicative of the player inputs, which correspond to an enabled feature for such inputs at a time of activation (e.g., pressing a “Max Bet” button or soft key to indicate a player's desire to place a maximum wager to play the wagering game). The inputs, once transformed into electronic data signals, are output to game-logic circuitry (e.g., the game-logic circuitry 40, shown in FIGS. 1 and 3) for processing. The electronic data signals are selected from a group consisting essentially of an electrical current, an electrical voltage, an electrical charge, an optical signal, an optical element, a magnetic signal, and a magnetic element.

The gaming machine 100 includes one or more value input/payment devices and value output/payout devices. In order to deposit cash or credits onto the gaming machine 10, the value input devices are configured to detect a physical item associated with a monetary value that establishes a credit balance on a credit meter presented by one or more presentation assemblies to the player. The physical item may, for example, be currency bills, coins, tickets, vouchers, coupons, cards, and/or computer-readable storage mediums. The deposited cash or credits are used to fund wagers placed on the wagering game played via the gaming machine 100. Examples of value input devices include, but are not limited to, a coin acceptor, the bill/ticket acceptor 128, the card reader/writer 130, a wireless communication interface for reading cash or credit data from a nearby mobile device, and a network interface for withdrawing cash or credits from a remote account via an electronic funds transfer. In response to a cashout input that initiates a payout from the credit balance on the credits meter, the value output devices are used to dispense cash or credits from the gaming machine 100. The credits may be exchanged for cash at, for example, a cashier or redemption station. Examples of value output devices include, but are not limited to, a coin hopper for dispensing coins or tokens, a bill dispenser, the card reader/writer 130, the ticket dispenser 128 for printing tickets redeemable for cash or credits, a wireless communication interface for transmitting cash or credit data to a nearby mobile device, and a network interface for depositing cash or credits to a remote account via an electronic funds transfer.

FIG. 6 depicts an example subsection of a secondary display assembly 122 of the gaming machine 100 according to one or more embodiments of the present disclosure. In particular, a secondary display panel 123 (and one adjacent panel 123) is shown. The secondary display panel 123 is formed as an array of pixels 143 that are configured to, as a whole, presents video and image data via emitted light having certain characteristics (e.g., color, intensity, etc.) for each pixel 143. The number of pixels 143 within a given display panel 123 may be referred to as the “resolution” of the display panel 123. Each pixel 143 is individually addressable by a display controller 141 of the game-logic circuitry (e.g., the game-logic circuitry 40, shown in FIGS. 1 and 3). The term “individually addressable” refers to the capability of the display controller 141 to send different control data (which may include power signals) that can result in different presentations by each pixel 143. For example, one pixel 143 may be controlled to present a green light, while an adjacent pixel 143 may be simultaneously controlled to present a red light. Additionally, the pixels 143 are configured to update on a periodic basis with new control or video data from the display controller 141. The update or refresh rate of the display panel 123 defines the timing of the updates to the display panel 123 (e.g., 30 Hz, 60 Hz, 120 Hz, etc.). The display controller 141 is configured to provide video and/or control data in a manner defined by the parameters of the display panel 123 and the underlying pixels 143.

In at least some embodiments, each pixel 143 is associated with one or more LEDs that emit light. In one example, each pixel 143 includes three adjacent LEDs with a color filter system that causes a first LED to emit red light, a second LED to emit green light, and a third LED to emit blue light. By combining these colors in various duty cycles, a range of colors can be perceived from a single pixel 143. The color filter system may be integrated within each LED (e.g., the LED is configured to emit light of a particular wavelength range), or the color filter system is positioned between the LED and the intended observation area (e.g., the external environment of the gaming machine 100). In certain embodiments, rather than having dedicated LEDs for each pixel 143, at least some LEDs may be shared by a plurality of pixels 143. In such embodiments, filters, such as liquid polarizing layers, or other suitable control structures may be used to facilitate the individually addressable nature of the pixels 143.

The LEDs of the display panel 123 are electrically coupled together to facilitate data and/or power communication. In one example, each LED has a separate data or control communication with the display controller 141 (e.g., via separate electrical traces and/or wires) with a shared power connection that enables multiple LEDs to be powered from a single power source, such as the display controller 141 or a dedicated power supply for the secondary display assembly 122. The LEDs may further share a single electrical ground (indicated by symbol 143), or independent grounds may be used. In certain embodiments, a single electrical ground 145 is shared not only by multiple pixels 143, but also may be shared across multiple secondary display panels 123.

LEDs are electronic devices that convert electrical energy into emitted light. To perform such a conversion, the LEDs have relatively precise operation parameters, such as particular input voltages, input currents, operating temperatures, and the like. Operating the LEDs outside of these parameters may cause the LEDs to not function properly and/or cause a shorted lifespan of the LEDs, including immediate failure. As a result, external phenomena like electrostatic discharge, which can be present in any electrically charged environments, may affect the LEDs and cause undesired harm and strain. Accordingly, ESD protection is desired for the LEDs of the secondary display panels. ESD protection from internal components of the gaming machine 100 can be designed through the use of predetermined physical spacing and electrical ground points configured through the gaming machine 100. However, external sources of ESD, such as other devices and players, can still be present in normal operating conditions and may approach the LEDs at a distance in which ESD is a possible occurrence.

Known emotive lighting systems provide physical barriers and air gaps that physically distance the LEDs from an external environment in which the gaming machine 100 is placed. The barriers can include benefits to emotive lighting, such as lenes or diffusion barriers that spread the emitted light from the LEDs across a surface or body of the barriers. Additionally, the LEDs in emotive lighting systems can be arranged in a configuration away from the external environment through the reliance of reflective layers capturing at least a portion of the emitted light while the LEDs are arranged, for example, behind a primary display.

In contrast to known emotive lighting systems, it is beneficial to arrange the LEDs forming the secondary display panels 123, particularly in flexible panels 123, to face outwards towards an external observation environment with limited physical barriers. That is, video or image content requires a level of precise output across all of the LEDs to create a unified image having the correct color and contrast without or having limited interference from air gaps and physical barriers that may cause visual artifacts or degradation to the image. For example, dust and smoke may build up in emotive lighting systems incorporating air gaps into the ESD protection of LEDs. Diffusion and reflection layers, in combination with the relatively low precision of emitted light required in emotive lighting can overcome the particulate build up in the air gaps of known emotive lighting systems, but such air gap particulates may result in dark spots or perceivable image degradation when attempting to view video content through a display assembly. Moreover, traditional ESD protection systems for emotive lighting may use a large copper ground plane integrated with or coupled to a substrate layer to diffuse ESD. However, display panels, particularly flexible display panels having modern pixel densities, are too dense to facilitate the ESD protection of emotive lighting, and the flexible display panels add additional structural complexity to such a ground plane. Conversely, applying a conducting ground plane to the display panels may inhibit the desired flexibility of the display panels. Accordingly, new methods and structures for ESD protection are needed to protect the LEDs of the secondary display assemblies.

FIG. 7 depicts a cross-sectional block diagram of an example secondary display panel 123, where the top of the panel 123 as shown in FIG. 7 faces an external area in which players and external devices are present, while the bottom of the panel 123 faces an internal structure of the corresponding gaming machine 100. The panel 123 includes an LED assembly 142, a substrate layer 144, an insulation layer 146, and an ESD protection layer 148. In other embodiments, the panel 123 includes additional, fewer, or alternative components, including those described elsewhere herein.

The LED assembly 142 includes a plurality of LEDs for presenting video content, particularly secondary game video content. The LED assembly 142 may include components associated with one or more LEDs to facilitate the functionality of the LED according to predefined operating parameters. For example, the LED assembly 142 may include driver circuitry, power conditioning circuitry, thermal heatsinks, sensors, and the like. The LED assembly 142 is in data and/or power communication with the display controller 141. More specifically, electrical traces, wires, contacts, and other electrical signal mediums extend between the LED assembly 142 and the display controller 141 to facilitate the transmission of electrical signals, which may include control data, analog control signals, and/or power signals. The display controller 141 may be coupled to each LED of the LED assembly 142 directly or indirectly (e.g., LEDs electrically connected in series to the display controller 141).

The LED assembly 142 is coupled to the substrate layer 144 that is configured to provide physical structure to the LED assembly 142 and to provide a medium for applying electrical traces, wires, and/or other components to the LED assembly 142 in a predefined configuration. For example, electrical traces may be run to each LED (or groups of LEDs) to facilitate power and control data delivery to the LEDs and corresponding drivers. The substrate layer 144 itself is electrically insulated to prevent or reduce unwanted electrical couplings between components secured to the substrate layer 144. In certain embodiments, the substrate layer 144 is at least partially thermally conductive or includes thermally conductive components (e.g., a heatsink) that transfer thermal energy away from the LEDs.

The LED assembly 142 is immersed within an insulation layer 146 that, similar to the substrate layer 144, provides physical structure to the LED panel 123 and electrically insulates each LED and other electrical component, thereby limiting electrical connections to the traces and other electrical coupling disposed within or on the substrate layer 144. The insulation layer 146 may be thermally conductive or insulative depending upon the thermal design of the display panel 123 and the LEDs. For example, at least some LED assemblies 142 may rely upon thermal dissipation systems integrated with or extending through the substrate layer 144, such as a heat sink on the opposing side of the substrate layer 144. In some embodiments, the insulation layer 146 is a coating or film applied at least to the LED assembly 142.

Unlike the substrate layer 144 positioned behind the LEDs, the insulation layer 146 is within the direct path of the light emitted from the LEDs to the external area. Accordingly, the insulation layer 146 is formed from a material or combination of materials that is substantially transparent, thereby enabling the emitted light to pass through substantially unimpeded to the external area. Suitable materials for forming the insulation layer 146 include, but are not limited to, epoxy, glue, urethane, silicone, glass, plastic, a conformal insulating coating, and the like.

In at least some embodiments, the insulation layer 146 is applied to the LED assembly 142 and the substrate layer 144 in a liquid, vapor, or other malleable form such that the LED assembly 142 is fully immersed in the insulation layer 146 after assembly. The insulation layer may be treated or otherwise set through a secondary process following the application of the insulation layer 146. For example, a cooling or heating process may be performed after application based on the material of the insulation layer 146 to facilitate setting the insulation layer is a rigid or semi-rigid state (i.e., to facilitate flexibility of the panel 123 without physical damage). In certain embodiments, the insulation layer 146 may not fully encompass the surface of the substrate layer 144, but rather is applied to the LEDs of the LED assembly and/or other electrical components. In such embodiments, the substrate layer 144 may be partially exposed, particularly in areas without electrically sensitive components.

The ESD protection layer 148 is physically coupled to or bonded with the insulation layer 146. The ESD protection layer 148 is an electrically conductive layer that intercepts and dissipates ESD, particularly ESD from an external source (e.g., player, external device, other gaming machine, etc.). The ESD protection layer 148 is spaced apart from the LED assembly 142 via the insulation layer 146 such that the any charges collected by the ESD protection layer remain within the ESD protection layer 148 and/or are directed to an electrical ground point, such as a mounting bracket for the panel 123. That is, the space between the LED assembly 142 and the ESD protection layer 148 is predetermined to avoid electrical connections between the LEDs and the ESD protection layer 148. In contrast to air gap-based LED systems, the insulation layer 146 is a solid or otherwise non-gaseous material that prevents particulates like dust and smoke from occupying the space between the LEDs and the external environment.

The ESD protection layer 148 is formed from a material or set of materials that is electrically conductive and sufficiently transparent to facilitate light passthrough from the LEDs to the external area. In some embodiments, the ESD protection layer 148 is a conductive coating or film applied to the insulation layer 146. In certain embodiments, the ESD protection layer 148 includes an application medium (e.g., a material that can be applied and adhered to the insulation layer 146) and one or more electrically conductive elements embedded within the medium. In one example, the ESD protection layer 148 is a urethane-based conductive layer. Example conductive materials for the ESD protection layer 148 include, but are not limited to, indium tin oxide (ITO), conductive polythiophene, clear static dissipative plastics, carbon nanotubes (and other carbon-based conductive materials), metal mesh, silver nanowires, polybrominated dibenzofurans (PBDFs), and the like.

Similar to the insulation layer 146, the ESD protection layer 148 is applied to the display panel 123 across an external surface of the insulation layer 146. The application method varies according to the material of the ESD protection layer 148 and the application state (e.g., liquid, vapor, etc.) of the material. In one example, the ESD protection layer 148 is applied in a liquid state to the external surface of the insulation layer 146 via an application tool, dipping the panel 123 into the liquid material, and the like. In another example, the ESD protection layer 148 is applied in a vapor state via a spray-on applicator. In yet another example, the ESD protection layer 148 is applied via sputter disposition. In a further example, an adhesive or other bonding material is applied between the ESD protection layer 148 and the insulation layer 146, or the external surface of the insulation layer 146 is heated or otherwise treated to a bondable state to apply the ESD protection layer 148. In certain embodiments, the ESD protection layer 148 is part of the insulation layer 146 (i.e., includes the same materials), but includes electrically conductive particulates or material. The electrically conductive particulates may be injected or otherwise applied to the insulation layer 146 during the application of the insulation layer 146 to form the ESD protection layer 148. In such embodiments, the LEDs are still electrically isolated from the ESD protection layer 148 via physical spacing and/or other electrically insulation barriers, includes barriers integrated with the LEDs. In one or more embodiments, the insulation layer 146 is formed from a material that can be electrically doped, chemically treated, or otherwise altered to facilitate the functionality of the ESD protection layer 148.

In at least some embodiments, the ESD protection layer 148 is applied over the entire external surface of the insulation layer 146. In other embodiments, the ESD protection layer 148 is applied in a configuration in which at least a portion of the external surface of the insulation layer 146 is exposed to the external area. For example, the ESD protection layer 148 may be applied in a grid-like configuration to the insulation layer 146 where the grid is applied to the boundaries of each pixel (e.g., the boundaries shown in FIG. 6). In some embodiments, in addition to applying the ESD protection layer 148, one or more treatment processes may be performed to facilitate the functionality of the ESD protection layer 148 and/or the display panel 123 as a whole. For example, an outer surface of the ESD protection layer 148 is polished, shaved, or otherwise treated to result in a substantially uniform thickness of the ESD protection layer 148, which facilitates substantially uniform light emission to the external area (and, by extension, substantially uniform of presentation of video content).

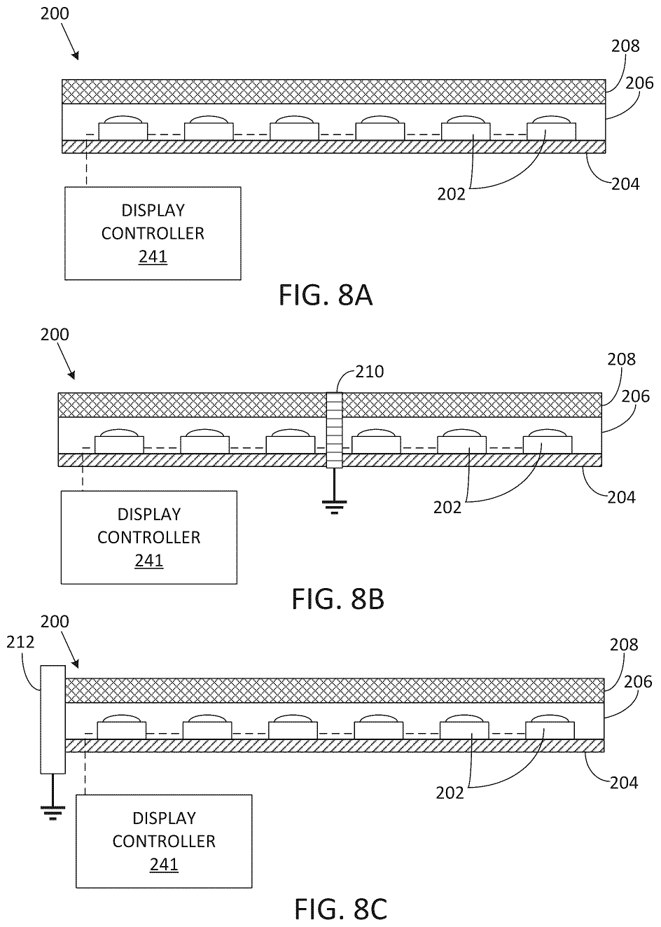

FIGS. 8A-8C depict a cross-sectional view of an example secondary display panel 200 of a gaming machine. The secondary display panel 200 includes a plurality of LEDs 202, a substrate layer 204, an insulation layer 206, and an ESD protection layer 208. In other embodiments, the display panel 200 includes additional, fewer, or alternative components, including those described elsewhere herein. In the illustrated orientation, when the secondary display panel 200 is installed on the gaming machine, the top of the panel 200 faces an external observation area of the gaming machine, while the bottom of the panel is oriented to face an internal housing of the gaming machine.

Referring now to FIG. 8A, the secondary display panel 200 is similar to the display panel 123 shown in FIG. 7. The LEDs 202 are oriented to emit light towards the external observable area and are coupled to the substrate layer 204, which is configured to act as a medium for electrical traces, wires, contacts, and the like for electrical signal transmission. The LEDs 202 are electrically coupled to a display controller 241 to enable the display controller 241 to control the operation of the LEDs 202. The LEDs 202 are arranged in a predefined manner (e.g., a grid-like arrangement) to facilitate the output of video and image content to the external observable area.

Although not shown in FIG. 8A, it is to be understood that the LEDs 202 are associated with a color filter system that enables emitted light from the LEDs to be filtered to certain colors, thereby enabling color images and videos to be presented across one or more display panels 200. In one example, each LED 202 includes an integrated color filter, where a combination of LEDs 202 having different color filters are used to recreate a range of colors. In another example, a color filter layer is applied along the path of the emitted light from the LEDs (e.g., within or coupled to the insulation layer 206).

In certain embodiments, each LED package (i.e., the physical item or housing that is applied to the substrate layer 204) is a group of LEDs 202. That is, while each package in the example embodiment is a single LED 202, the package may house multiple LEDs 202 in other embodiments. Grouping LEDs 202 into a single package may be desirable to facilitate dynamic color output from a single LED package, where each LED 202 is associated with a different color filter (e.g., red, green, and blue) to facilitate the recreation of a range of color output.

In the example embodiment, the LEDs 202 are immersed within an insulation layer 206. The insulation layer 206 is formed from a material that is at least electrically insulative to prevent unwanted electrical couplings between LEDs 202 and other circuitry disposed on the substrate layer 204. The insulation layer 206 may be configured to be thermally conductive or insulative depending upon the thermal constraints and configuration of the display panel 200 and the LEDs. For example, a heatsink (not shown) may be applied to the substrate layer 204 in a manner that facilitates heat dissipation without requiring assistance from the insulation layer 206. In another example, the insulation layer 206 is thermally conductive and in contact with an external heatsink or other thermally conductive component for heat dissipation.

The insulation layer 206 is formed from a non-gaseous material or combination of materials such that no air gap is formed between the LEDs 202 and the ESD protection layer 208. In at least some embodiments, the insulation layer 206 is a solid material that facilitates light passthrough from the LEDs 202. The insulation layer 206 and the substrate layer 204 are configured to provide structural integrity to the display panel 200. In some embodiments, the insulation layer 206 and/or the substrate layer 204 are configured to facilitate the panel 200 to be flexible. The flexibility is configured through the material of the layers and/or the design of the layers (e.g., segmented sections moveably coupled together).

The ESD protection layer 208, similar to the ESD protection layer 148 shown in FIG. 7, is an electrically conductive layer physically coupled to or bonded with the insulation layer 206. The ESD protection layer 208 is exposed to the external observation area to intercept ESD from external sources (e.g., people, external devices, etc.) and dissipate the charge away from the LEDs 202, thereby protecting the LEDs 202 from damage resulting from the ESD. In addition to being electrically conductive, the ESD protection layer 208 is configured to enable light emitted by the LEDs 202 to pass through substantially unimpeded or with limited observable degradation. The light passthrough characteristic of the ESD protection layer 208 is facilitated by the material choice of the ESD protection layer 208 and/or the application of the ESD protection layer 208 to the insulation layer 206.

To dissipate electric charges collected from ESD, the ESD protection layer 208 is electrically coupled to an electrical ground of the gaming machine. Each panel 200 may have an independent ground, or adjacent panels 200 share a common ground point such that collected charges may be transported between adjacent panels 200 to the ground point. Additionally or alternatively, the ESD protection layer 208 may be configured to store collected charges (i.e., via capacitance) such that the storage charge is dissipated over time.

FIGS. 8B and 8C depict two example electrical grounds for the display panel 200. More specifically, FIG. 8B depicts the display panel 200 including a ground post 210, and FIG. 8C depicts the panel 200 coupled to or proximate to an electrically grounded bracket 212. Other suitable grounding structures may be used in other embodiments, including combinations of the grounding types described herein. In some embodiments, each display panel 200 of the gaming machine is configured to include a ground point. In other embodiments, less than all display panels 200 include a ground point. For example, with respect to FIG. 8C, the bracket 212 may be present surrounding a group of display panels 200, where any internal display panels 200 rely upon external display panels 200 of the group and the bracket 212 for electrical grounding.

With respect to FIG. 8B, the display panels 200 include one or more ground posts 210. The ground posts 210 are electrically conductive components that are inserted into or otherwise embedded with the display panel 200. The material or combination of materials forming the ground posts 210 may provide, in addition to being electrically conductive, thermal dissipation from the body of the display panel 200 and/or provide rigidity or structure to the body of the panel 200. In certain embodiments, the ground posts 210 may be used to physically couple layers of the display panel together (e.g., the ground posts 210 act as fasteners through the display panel 200.

In the example embodiment, the ground post 210 extends from the ESD protection layer 208 through the insulation layer 206 and at least up to the substrate layer 204. In other embodiments, rather than extending through the body of the display panel 200 as shown in FIG. 8B, the posts 210 may extend in a different direction from the ESD protection layer 208. In one example, the posts 210 extend outward from the ESD protection layer 208 perpendicular to the illustrated direction (i.e., from the sides of the panel 200) to contact an external ground point. In another example, the posts 210 extend from an external face of the ESD protection layer 208. The ground posts 210 are spaced apart from and electrically insulated from (e.g., by at least the insulation layer 206) the LEDs 202. In some embodiments, the substrate layer 204 includes an electrical ground (e.g., using the traces and contact points of the circuitry provided thereon), and the ground post 210 is electrically coupled to the ground on the substrate layer 204. In other embodiments, the ground post 210 extended through the substrate layer 204 to electrically (and, in certain embodiments, physically) couple to an external electrical ground. For example, when mounted to the gaming machine, the ground post 210 may be exposed through the substrate layer 204 to contact with (or otherwise be electrically coupled to) an external mounting bracket, where the bracket is electrically grounded through the cabinet of the gaming machine.

FIG. 8C depicts the display panel 200 in contact with a bracket 212. The bracket 212 is an electrically-conductive external component of the gaming machine for mounting, supporting, or otherwise protecting the display panel 200 and/or other adjacent components not shown. In certain embodiments, the bracket 212 is integrated within a secondary presentation assembly including the display panel 200, where the secondary presentation assembly is configured to be mounted to a cabinet or housing of the gaming machine.

In the example embodiment, the bracket 212 is electrically coupled to an electrical ground. The electrical ground may be, for example, a ground surface upon which the gaming machine stands or another suitable electrical ground. The bracket 212 may be in direct physical contact with the electrical ground or physically separated (e.g., via intermediate components, air gaps, and the like) in a suitable configuration to create an electrical pathway for charges from the ESD protection layer 208 to be dissipated.

In the illustrated embodiment, the bracket 212 is physically and electrically coupled to the ESD protection layer 208. The bracket 212 may be spaced apart from and electrically isolated from the LEDs 202 and any other circuitry on the substrate layer 204 to prevent the charges from the ESD protection layer 208 being directed to the circuitry of the display panel 200. In other embodiments, the bracket 212 may be physically spaced apart from but physically proximate to the ESD protection layer 208 to enable the collected charges from the ESD protection layer 208 to “jump” the gap or space between the ESD protection layer 208 and the bracket 212. The size of the gap between the ESD protection layer 208 and the bracket 212 may be calibrated to ensure the charge dissipation occurs in a controlled manner (i.e., within a predefined range of collected electrical charge).

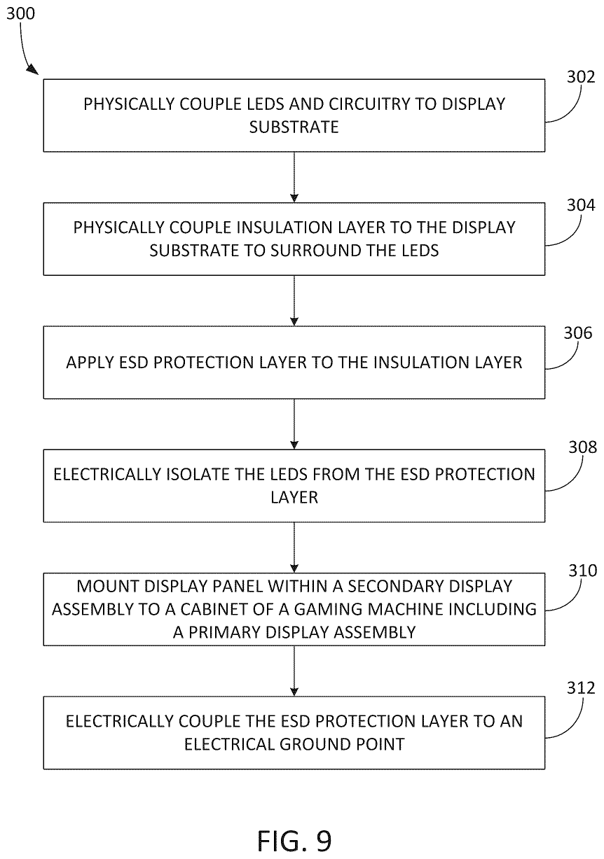

FIG. 9 depicts an example method 300 of assembling and installing an example secondary display panel of a gaming machine (e.g., the machine shown in FIG. 4). The method 300 is performed to assemble and install a secondary display panel similar to the display panel 200 (shown in FIGS. 8A-8C) within a secondary display assembly of the gaming machine. In other embodiments, particularly embodiments in which the display panel has a different configuration, the method 300 includes additional, fewer, or alternative steps, including those described elsewhere herein.

The method 300 begins at step 302 by physically coupling a plurality of LEDs and other circuitry to a display substrate (i.e., a substrate layer). The LEDs are configured to present video data when installed at a gaming machine. The other circuitry is configured to facilitate the functionality of the LEDs and/or other suitable functions associated with the secondary display assembly. For example, the circuitry may include, without limitation, power circuitry, LED driver circuitry, sensor circuitry, and the like. The display substrate further includes electrical connections between the circuitry to facilitate the transmission of electrical signals. That is, the display substrate may include electrical traces, contacts, through-holes, wires, and/or other suitable electrical connectors to electrically couple the circuitry together and to other external electrical components. The electrical connections may be integrated with the display substrate or coupled to the display surface. The physical coupling between the circuitry and the display substrate may be via the electrical connections and suitable bonding material (e.g., solder) and/or other suitable coupling methods and materials. In one example, adhesive or other bonding material is applied between the circuitry and the display substrate. In another example, the display substrate includes physical features (e.g., fastener holes, brackets, etc.) that, when paired with corresponding physical structure of the circuitry, creates a physical bond.

The display substrate is configured to provide physical structure to the LEDs and other circuitry. As described herein, the display substrate is also configured to facilitate the mounting or installation of the display panel to the gaming machine. The LEDs are coupled to the display substrate in an orientation to emit light (and, by extension, video content) away from the display substrate and towards an external area of the gaming machine when the display panel is installed. That is, the LEDs are mounted on a surface of the display substrate that faces the external area, where the opposing face of the display substrate may face an internal body of the gaming machine.

At step 304, an insulation layer is applied to the display panel by physically coupling the insulation layer to the display substrate. In at least some embodiments, the insulation layer surrounds the LEDs such that the LEDs are not exposed to the external area. The insulation layer is electrically insulated to limit or otherwise reduce electrical couplings beyond the electrical pathways defined by the LEDs, circuitry, and electrical connectors coupled to the display substrate.

The insulation layer is applied through methods suitable to the material or materials of the insulation layer. For example, at least some insulation layers may be applied in a liquid or other flowable state and set in a solid or semi-solid state (e.g., via temperate or pressure changes). In another example, an adhesive or other bonding material is applied between the insulation layer, the display substrate, and the LEDs. In a further example, fasteners or other suitable physical connectors may be used, such as external brackets that apply a force to the display panel, thereby maintaining the physical coupling between layers.

At step 306, an ESD protection layer is applied to the insulation layer such that the ESD protection layer is exposed to the external area. The ESD protection layer is an electrically conductive layer configured to intercept and dissipate electrostatic discharge, particularly discharge originating from the external area and any external sources of electrical charge (e.g., people, external devices, etc.). The ESD protection layer is physically bonded to the insulation layer such that there is no air gap between to collect particulates that may affect the presentation of video content by the display panel.

The application method of the ESD protection layer varies based on the materials of the ESD protection layer and/or the insulation layer and/or other suitable assembly condition. For example, and without limitation, the ESD protection layer is applied to the insulation layer via a spray application, a vapor disposition application, a sputter disposition application, brushed application, and the like. In one example, the ESD protection layer is an ITO film that is applied to the insulation layer via sputter disposition. In another example, the ESD protection layer has a urethane-based medium with embedded conductive elements, and the ESD protection layer is applied via spray application or brushed onto the insulation layer.

In certain embodiments, following the application of the ESD protection layer, the ESD protection layer may be further adjusted to facilitate the light emission from the LEDs. For example, a portion of the ESD protection layer may be removed to ensure a relatively thin, uniform ESD protection layer spans the entire display panel. In another example, the exposed surface of the ESD protection layer (i.e., the surface facing the external area) may be treated, polished, or otherwise adjusted to facilitate substantially unimpeded light emission from the LEDs to the external area. In certain embodiments, a surface coating is applied to the ESD protection layer to secure the ESD protection layer to the display panel and/or protect the ESD protection layer from external damage, where the surface coating is configured (e.g., via material composition, thickness, and/or the like) to enable the ESD protection to provide ESD protection to the LEDs.

At step 308, the LEDs are electrically isolated from the ESD protection layer. In at least some embodiments, the electrical isolation is a result of the particular configuration of the layers and components forming the display panel. That is, the electrical isolation of the step 308 may be a direct result of applying the ESD protection layer at the step 306 in a particular manner. In the example embodiment, the ESD protection layer is applied to the insulation layer and is physically separated from the LEDs, where the electrical insulation provided by the insulation layer between the LEDs and the ESD protection layer is sufficient to prevent electrical couplings between the LEDs and the ESD protection layer within expected operating conditions.

Following the steps 302-308, the display panel is assembled. In some embodiments, additional layers, components, and the like are included within the display panel, and therefore the method 300 in such embodiments include additional or alternative steps to assemble the additional elements. In one example, the display panel further includes mounting components, such as fastener holes, brackets, clips, and the like to facilitate the installation of the display panel. The steps 302-308 may be repeated for a plurality of display panels to be installed as described herein.

At step 310, the display panel is mounted within a secondary display assembly to a cabinet of a gaming machine. The secondary display assembly may include a plurality of display panels that are coupled together into one or more sets of panels such that each set may act as a unified display (i.e., video content is presented across one set of panels). Other suitable components, such as mounting elements, wires, and the like may also be included within the secondary display assembly. In some embodiments, the secondary display assembly is assembled prior to mounting the display panels to the cabinet of the gaming machine. In other embodiments, the secondary display assembly is formed by mounting the display panels together on the gaming machine.

In the example embodiment, the gaming machine includes a primary display assembly for presenting primary game content (e.g., spinning reels, symbols arrays, award wheels, etc.). The primary display assembly, relative to a player position within the external area and the secondary display assembly, is mounted to the cabinet in substantially central or focused position. It is to be understood that the term “central position” is not intended to limit the position of the primary display assembly to a true center position of the gaming machine. Rather, a player in the player position is aligned with the primary display to facilitate visual focus on the primary game content being presented. In contrast, the secondary display assembly is positioned adjacent to or away from the primary display assembly to present secondary game and presentation content. In one example, the secondary display assembly is configured to extend in parallel along at least one edge of the primary display assembly. In a further example, the secondary display assembly extends from a base of the gaming machine to a top of the gaming machine at a depth offset from the primary display assembly when viewed from the player position, thereby creating a depth contrast between the primary and secondary game content presented by the respective display assemblies.

The installation of the display panels includes the use of fasteners, clips, brackets, adhesives, and/or other suitable installation elements to ensure secure mounting of the display panels. In some embodiments, the display panels are flexible, and the installation point for at least some display panels may mount the display panels in a curved configuration.

At step 312, the ESD protection layer of each display panel is electrically coupled to an electrical ground point. The electrical ground point may be internal to the display panel or external to the display panel. Internal ground points may be provided during the assembly of the display panel. In at least one example, one or more ground posts within the display panel are electrically coupled between the ESD protection layer and an electrical ground. In one such embodiment, the grounding posts physically extend from the ESD protection through the insulation layer (while being spaced apart from the LEDs) and at least up to the display substrate. The grounding posts may terminate at the display substrate and connect to a ground point via the connectors of the display substrate, or the grounding posts extend through the display substrate to contact an external grounding point, such as a mounting bracket of the gaming machine cabinet.

External ground points may include other display panels, where the ESD protection layers of adjacent display panels are electrically coupled, thereby enabling multiple display panels to share a common ground point. The external ground points may additionally or alternatively include other electrically conductive components physically coupled to or physically proximate to the ESD protection layer, such as mounting brackets, dedicated ground connectors (e.g., wires extended to a ground point), and the like. In embodiments in which the ESD protection layer and the external components are physically separate, the gap therebetween may be sufficiently small to enable electrical charges collected by the ESD protection layer to be dissipated across the gap prior to the collected charges approaching an amount that may overcome the electrical insulation provided by the insulation layer.

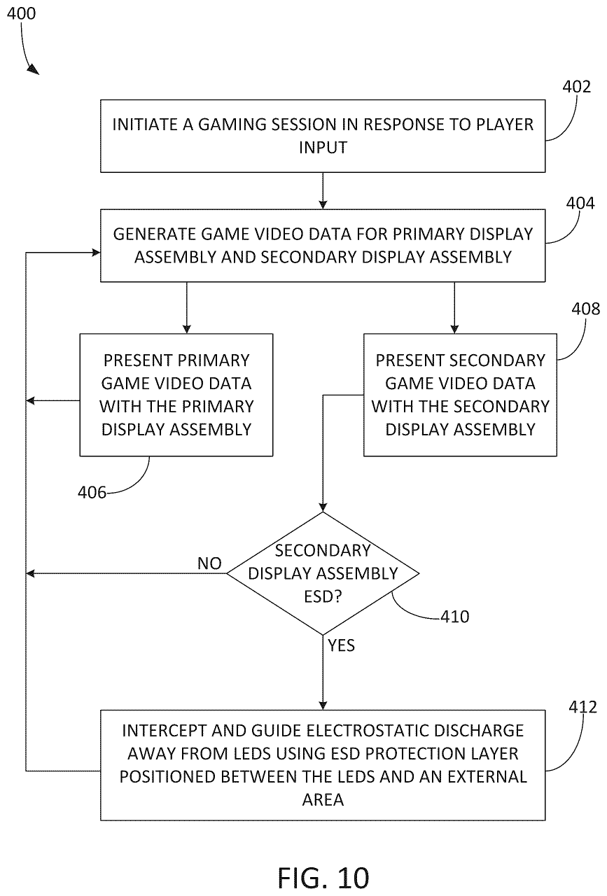

FIG. 10 depicts an example method 400 for operating a gaming machine. The gaming machine includes at least a primary display assembly and a secondary display assembly, where the primary display assembly occupies a focal position on the gaming machine from a player position, and the secondary display assembly occupies a secondary position on the gaming machine. In at least some embodiments, the secondary position causes the secondary display assembly to appear as it is extending from one or more edges of the primary display assembly from the player position. The secondary display assembly is formed by a plurality of display panels, such as the panels shown in FIGS. 8A-8C with an ESD protection layer exposed to the external area surrounding the gaming machine and electrically coupled to an electrical ground point.

The gaming machine further includes game-logic circuitry in communication with the primary and secondary display assemblies to perform the steps of the method 400. In other embodiments, the method 400 includes additional, fewer, or alternative steps, including those described elsewhere herein.

At step 402, the game-logic circuitry initiates a gaming session at the gaming machine in response to player input. The player input may include, for example, providing a credit input to establish a credit balance, pressing a button of the gaming machine, or triggering a presence sensor of the gaming machine. The gaming machine, via the primary display assembly or another suitable display assembly, may prompt the player for additional input, such as credit input or player credentials, during the initiation of the gaming session.

The gaming session includes at least one suitable game for play, which may be conducted through the use of player input, monitoring the state of a credit balance, random or partially random outcomes, and the like. To provide the player feedback of the gameplay, the game-logic circuitry is configured to generate game video data at step 404. More specifically, to provide a unified game presentation, the game-logic circuitry generates separate game video data for the primary and secondary display assemblies to be presented substantially simultaneously. The generated game video data includes a plurality of images or frames of video data the indicate various information, game elements, animations, and the like to the player, thereby providing visual feedback on the gameplay of the gaming session. The different content of the game video data between the display assemblies enables the gaming machine to present an enhanced variety of game presentations, where the secondary game content supplements or otherwise enhances the primary game content.

At step 406, the primary game video data generated by the game-logic circuitry is transmitted to the primary display assembly and presented by the primary display assembly. Substantially simultaneously, secondary game video data generated by the game-logic circuitry is transmitted to the secondary display assembly and presented by the display panels of the secondary display assembly at step 408. In some embodiments, the primary and secondary game video data includes timestamps or other suitable synchronization data to facilitate substantially synchronized presentations.

The generation and presentation game video data (i.e., steps 404-408) is repeated throughout the gaming session until the gaming session is concluded (i.e., detection of a cashout input, which initiates a cashout sequence to conclude the gaming session). During the gaming session, at step 410, the ESD protection layer of the display panels forming the secondary display assembly are configured to protect against electrostatic discharge, particularly discharge originating from people, devices, and the like external to the gaming machine. If electrostatic discharge occurs at the secondary display assembly, at step 412, the ESD protection layer intercepts and guides the discharge away from the LEDs within the display panels to a grounding point, thereby avoiding undesirable wear or damage to the LEDs.

Although the foregoing systems and methods are described above with respect to gaming machines, it is to be understood that the flexible display panels with integrated ESD protection may be used in other suitable gaming devices, such as gaming kiosks, gaming terminals associated with table games, card shufflers and shoes, and the like.

In this description, numerous specific details are set forth. However, it is understood that embodiments of the invention may be practiced without these specific details. In other instances, well-known circuits, structures, and techniques have not been shown in detail in order not to obscure the understanding of this description. Note that in this description, references to “one embodiment” or “an embodiment” mean that the feature being referred to is included in at least one embodiment of the invention. Further, separate references to “one embodiment” in this description do not necessarily refer to the same embodiment; however, neither are such embodiments mutually exclusive, unless so stated and except as will be readily apparent to those of ordinary skill in the art. Thus, the present invention can include any variety of combinations and/or integrations of the embodiments described herein. Each claim, as may be amended, constitutes an embodiment of the invention, incorporated by reference into the detailed description. Moreover, in this description, the phrase “exemplary embodiment” means that the embodiment being referred to serves as an example or illustration.

Block diagrams illustrate exemplary embodiments of the invention. Flow diagrams illustrate operations of the exemplary embodiments of the invention. The operations of the flow diagrams are described with reference to the example embodiments shown in the block diagrams. However, it should be understood that the operations of the flow diagrams could be performed by embodiments of the invention other than those discussed with reference to the block diagrams, and embodiments discussed with references to the block diagrams could perform operations different than those discussed with reference to the flow diagrams. Additionally, some embodiments may not perform all the operations shown in a flow diagram. Moreover, it should be understood that although the flow diagrams depict serial operations, certain embodiments could perform certain of those operations in parallel or in a different sequence.

Each of these embodiments and obvious variations thereof is contemplated as falling within the spirit and scope of the claimed invention, which is set forth in the following claims. Moreover, the present concepts expressly include any and all combinations and subcombinations of the preceding elements and aspects.

What is claimed is:

1. A gaming machine comprising:
a cabinet;
a primary display coupled to the cabinet, the primary display configured to present primary game video data; and
at least one secondary display assembly coupled to the cabinet and configured to present secondary game video data, the at least one secondary display assembly comprising:
a plurality of light emitting diodes (LEDs) configured to present video data towards an external area surrounding the gaming machine;
a display substrate coupled to the plurality of LEDs, the display substrate including display circuitry electrically coupling the plurality of LEDs together for presenting the secondary game video data;
an insulation layer physically coupled to the display substrate and surrounding the plurality of LEDs; and
an electrostatic discharge (ESD) layer physically coupled to the insulation layer and physically spaced apart from the plurality of LEDs, the ESD layer being electrically conductive to guide electrostatic discharge from the external area away from the plurality of LEDs, wherein the ESD layer is electrically isolated from the display circuitry by the insulation layer.

2. The gaming machine of claim 1, wherein the ESD layer is electrically coupled to a grounding point, the ESD layer configured to guide the electrostatic discharge towards the grounding point.

3. The gaming machine of claim 2, wherein the cabinet includes the grounding point adjacent to one or more of the at least one secondary display assembly.

4. The gaming machine of claim 2, wherein the grounding point is a grounding post extending through the display substrate to the cabinet.

5. The gaming machine of claim 1, wherein the at least one secondary display assembly includes a plurality of secondary display panels physically coupled together to extend adjacent to the primary display.

6. The gaming machine of claim 5, wherein the ESD layers of the plurality of secondary display assemblies are electrically coupled together and share a common grounding point.

7. The gaming machine of claim 1, wherein the ESD layer is exposed to the external area surrounding the gaming machine, the ESD layer separating the insulation layer from the external area.

8. The gaming machine of claim 1, wherein the ESD layer is physically bonded to the insulation layer through at least one of a spray application, a brushed application, a vapor disposition application, and a sputter disposition application.

9. The gaming machine of claim 1, wherein the ESD layer is an indium tin oxide (ITO) film.

10. A secondary display assembly of a gaming machine, the secondary display assembly configured to couple to a cabinet of the gaming machine, wherein the secondary display assembly comprises:
a plurality of light emitting diodes (LEDs) configured to present game video data towards an external area surrounding the gaming machine;
a display substrate coupled to the plurality of LEDs, the display substrate including display circuitry electrically coupling the plurality of LEDs together for presenting the game video data;
an insulation layer physically coupled to the display substrate and surrounding the plurality of LEDs; and
an electrostatic discharge (ESD) layer physically coupled to the insulation layer and physically spaced apart from the plurality of LEDs, the ESD layer being electrically conductive to guide electrostatic discharge from the external area away from the plurality of LEDs, wherein the ESD layer is electrically isolated from the display circuitry by the insulation layer.

11. The secondary display assembly of claim 10, wherein the ESD layer is electrically coupled to a grounding point, the ESD layer configured to guide the electrostatic discharge towards the grounding point.

12. The secondary display assembly of claim 11, wherein the cabinet includes the grounding point adjacent to the secondary display assembly.

13. The secondary display assembly of claim 11, wherein the grounding point is a grounding post extending through the display substrate to the cabinet.

14. The secondary display assembly of claim 10, wherein the secondary display assembly includes a plurality of secondary display panels physically coupled together to extend adjacent to a primary display of the gaming machine.

15. The secondary display assembly of claim 14, wherein the ESD layers of the plurality of secondary display panels are electrically coupled together and share a common grounding point.

16. The secondary display assembly of claim 10, wherein the ESD layer is exposed to the external area surrounding the gaming machine, the ESD layer separating the insulation layer from the external area.

17. The secondary display assembly of claim 10, wherein the ESD layer is physically bonded to the insulation layer through at least one of a spray application, a brushed application, a vapor disposition application, and a sputter disposition application.

18. The secondary display assembly of claim 10, wherein the ESD layer is an indium tin oxide (ITO) film.

19. A method of operating a gaming machine having a primary display assembly and at least one secondary display assembly, the method comprising:
initiating, by the gaming machine in response to player input, a gaming session;
presenting, via the primary display assembly, primary game video data associated with the gaming session;
presenting, via the at least one secondary display assembly, secondary game video data associated with the gaming session by emitting light from a plurality of light-emitting diodes (LEDs) of the at least one secondary display assembly arranged to present video data towards an external area surrounding the gaming machine, the primary game video data and the secondary game video data presented concurrently, wherein the plurality of LEDs are surrounded by an insulation layer; and
in response to electrostatic discharge (ESD) from the external area occurring at the at least one secondary display assembly, guiding, by an ESD layer of the at least one secondary display assembly, the ESD away from the plurality of LEDs, wherein the ESD layer is physically coupled to the insulation layer and physically spaced apart from the plurality of LEDs, the ESD layer being electrically isolated from the plurality of LEDs.

20. The method of claim 19, wherein the ESD layer is electrically coupled to a grounding point, the ESD layer configured to guide the electrostatic discharge towards the grounding point.
